(19) United States
(12) Patent Application Publication
(10) Pub. No.: US 2012/0261812 A1
(43) Pub. Date: Oct. 18, 2012

(54) SEMICONDUCTOR CHIP WITH PATTERNED UNDERBUMP METALLIZATION

(76) Inventor: Roden R. Topacio, Markham (CA)

(21) Appl. No.: 13/086,672

(22) Filed: Apr. 14, 2011

(51) Int. Cl. H01L 23/48; H01L 21/60

(52) U.S. Cl. 257/737; 438/121; 257/E23.021; 257/E21.508

(57) ABSTRACT

Various semiconductor chip solder bump and underbump metallization (UBM) structures and methods of making the same are disclosed. In one aspect, a method is provided that includes providing a semiconductor chip that has a conductor pad and a passivation structure over the conductor pad. A first metallic layer is applied on the passivation structure and in electrical contact with the conductor pad. The first metallic layer covers a first portion but not a second portion of the passivation structure. A second metallic layer is applied to the first metallic layer. A polymer layer is applied to the second metallic layer. The polymer layer includes a first opening in alignment with the first metallic layer that exposes a portion of the second layer. A conducting solder barrier layer is applied to the exposed portion of the second metallic layer.

### BACKGROUND OF THE INVENTION

1. Field of the Invention

This invention relates generally to semiconductor processing, and more particularly to semiconductor chip solder bump structures and methods of making the same.

2. Description of the Related Art

Flip-chip mounting schemes have been used for decades to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

In one conventional process, the connection of the solder bump to a particular I/O site of a semiconductor chip entails forming an opening in a top-level dielectric layer of a semiconductor chip proximate the I/O site and thereafter depositing metal to establish an underbump metallization (UBM) structure. The solder bump is then metallurgically bonded to the UBM by reflow. In a conventional process for forming a UBM, a titanium layer is blanket deposited on a passivation structure. Thereafter a copper plating layer is deposited on the titanium layer. A polyimide layer is next patterned on the copper plating layer. The patterning of the polyimide layer involves a bake step that gives rise to the formation of an intermetallic layer of a non-stoichiometric solution of titanium and copper between the titanium and copper layers. The intermetallic layer is ubiquitous, due to the blanket nature both the titanium and copper layers, and remarkably resistant to etchants used to etch copper and titanium. To prevent the copper and titanium layers from shorting between bump sites, etch processes are performed. However, the intermetallic layer may linger even after such etches and lead to shorts.

One conventional solution involves the use of titanium-tungsten as an adhesion layer. However, the use of titanium-tungsten instead of titanium comes at a substantial cost premium.

The present invention is directed to overcoming or reducing the effects of one or more of the foregoing disadvantages.

### SUMMARY OF EMBODIMENTS OF THE INVENTION

In accordance with one aspect of an embodiment of the present invention, a method is provided that includes providing a semiconductor chip that has a conductor pad and a passivation structure over the conductor pad. A first metallic layer is applied on the passivation structure and in electrical contact with the conductor pad. The first metallic layer covers a first portion but not a second portion of the passivation structure. A second metallic layer is applied to the first metallic layer. A polymer layer is applied to the second metallic layer. The polymer layer includes a first opening in alignment with the first metallic layer that exposes a portion of the second metallic layer. A conducting solder barrier layer is applied to the exposed portion of the second metallic layer.

In accordance with another aspect of an embodiment of the present invention, a method of coupling a semiconductor chip to a circuit board is provided. The semiconductor chip has a first conductor pad, a passivation structure, and an underbump metallization in electrical contact with the conductor pad. The underbump metallization includes a first metallic layer on the passivation structure and in electrical contact with the conductor pad. The first metallic layer covers a first portion but not a second portion of the passivation structure. A second metallic layer is on the first metallic layer and a polymer layer is on the second metallic layer. The polymer layer includes a first opening in alignment with the first metallic layer that exposes a portion of the second metallic layer. A conducting solder barrier layer is on the exposed portion of the second metallic layer. The method further includes coupling a solder structure to the underbump metallization and coupling the solder structure to the circuit board.

In accordance with another aspect of an embodiment of the present invention, an apparatus is provided that includes a semiconductor chip that has a conductor pad and a passivation structure over the conductor pad. A first metallic layer is on the passivation structure and in electrical contact with the conductor pad. The first metallic layer covers a first portion but not a second portion of the passivation structure. A second metallic layer is on the first metallic layer. A polymer layer is on the second metallic layer. The polymer layer includes a first opening in alignment with the first metallic layer that exposes a portion of the second metallic layer. A conducting solder barrier layer is on the exposed portion of the second metallic layer.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mountable on a circuit board;

FIG. 2 is a sectional view of FIG. 1 taken at section 2-2;

FIG. 3 is a sectional view of a small portion of a conventional semiconductor chip following conventional passivation structure etching;

FIG. 4 is a sectional view like FIG. 3, but of a conventional titanium layer blanket deposition;

FIG. 5 is a sectional view like FIG. 4, but depicting conventional copper plating layer blanket deposition;

FIG. 6 is a sectional view like FIG. 5, but depicting polyimide layer application and patterning and titanium-copper intermetallic layer formation;

FIG. 7 is a sectional view like FIG. 6, but depicting dry film pattering;

FIG. 8 is a sectional view like FIG. 7, but depicting solder barrier and solder plating;

FIG. 9 is a sectional view like FIG. 8, but depicting dry film removal;

FIG. 10 is a sectional view like FIG. 9, but depicting etching of the copper plating layer and ultimate exposure of the etch resistant intermetallic layer;

FIG. 11 is a sectional view like FIG. 2, but depicting exemplary formation of a conductor pad and overlying passivation structure;

FIG. 12 is a sectional view like FIG. 11, but depicting exemplary adhesion layer application;

FIG. 13 is a sectional view like FIG. 12, but depicting exemplary masking of the adhesion layer;

FIG. 14 is a sectional view like FIG. 13, but depicting exemplary patterning of the adhesion layer to expose a portion of the passivation structure;

FIG. 15 is a sectional view like FIG. 14, but depicting exemplary application of a metallic layer on the adhesion layer;

FIG. 16 is a sectional view like FIG. 15, but depicting exemplary application and patterning of a polymer layer on the metallic layer;

FIG. 17 is a sectional view like FIG. 16, but depicting exemplary masking of the metallic layer;

FIG. 18 is a sectional view like FIG. 17, but depicting exemplary plating of a conducting solder barrier layer and a solder structure;

FIG. 19 is a sectional view like FIG. 18, but depicting exemplary mask removal;

FIG. 20 is a plan view of an exemplary UBM; and

FIG. 21 is a plan view of an alternate exemplary UBM.

### DETAILED DESCRIPTION OF SPECIFIC EMBODIMENTS

Various embodiments of a semiconductor chip are described herein. One example includes solder bump connection structures, such as UBMs, fabricated on respective conductor pads. A given UBM includes an adhesion layer, a plating layer and a conducting solder barrier layer. The adhesion layer is patterned prior to application of the plating layer to reduce the extent of an adhesion layer-to-plating layer interface. If left as is, the adhesion layer-to-plating layer interface produces an intermetallic layer, which is etch resistant and can thus leave bump-to-bump shorts. Additional details will now be described.

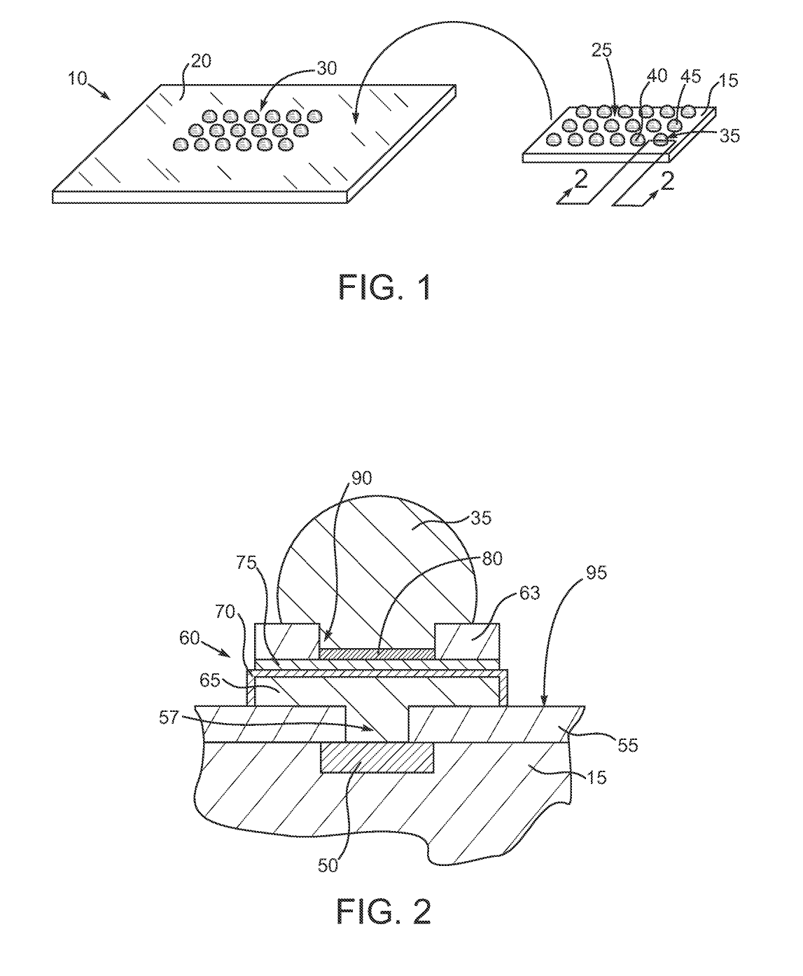

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 that may be mounted on a circuit board 20. In this illustrative embodiment, and to illustrate certain features of the semiconductor chip 15, the chip 15 is shown detached and flipped over from its mounting position on the circuit board 20. The semiconductor chip 15 includes multiple solder bumps 25, which are designed to metallurgically bond with the corresponding array of solder structures 30 on the circuit board 20 and form plural solder joints or other type of solder connections when the semiconductor chip 15 is mounted to the circuit board 20. Note that three of the solder bumps 25 are separately labeled 35, 40 and 45. The solder bump 35 will be used to illustrate additional features of the semiconductor chip 15 in conjunction with subsequent figures.

FIG. 2 is a sectional view of FIG. 1 taken at section 2-2. Before turning to FIG. 2 in earnest, it should be noted that section 2-2 passes through a portion of the semiconductor chip 15 that includes the solder bump 35. The following discussion of the solder bump 35 will be illustrative of the other solder bumps 25 and related structures. Attention is now turned to FIG. 2. For simplicity of illustration, the full depth of the semiconductor chip 15 is not depicted and the features thereof are not drawn to scale. The solder bump 35 is designed to provide an electrical connection between the circuit board 20 and an underlying pad 50. The skilled artisan will appreciate that the pad 50 may be part of a topmost layer of interconnect metallization and may be connected to various other electrical structures both laterally and vertically that form up an interconnect system for the semiconductor chip 15. In addition, the skilled artisan will appreciate that somewhere within the confines of the semiconductor chip 15 an active device region with multitudes of integrated circuit elements such as transistors, resistors and others is positioned.

A variety of intervening structures are positioned between the solder bump 35 and the conductor pad 50. Proceeding from bottom to top, these intervening structures include a passivation structure 55, an under bump metallization (UBM) structure 60 and a polymer layer 63. The passivation structure 55 is designed to protect the conductor pad 50 from physical damage and contamination prior to the manufacture of the UBM and attachment of the solder bump 35. Exemplary materials include silicon dioxide, silicon nitride, polyimide, laminates of these or the like.

The UBM 60 is designed to satisfy a few important objectives, namely, to bond to the overlying solder bump 35 or other solder structure, to establish a conductive interface with an underlying conductor structure, in this case the conductor pad 50, and to bond as necessary with underlying or surrounding dielectrics, such as the passivation structure 55, all while providing a barrier to the diffusion of solder constituents into underlying conductor structures, which might otherwise degrade those conductor structures. In this illustrative embodiment, the UBM 60 may consist of an adhesion layer 65 in metallurgical contact with the pad 50, an intermetallic titanium copper layer 70 that essentially coats the sides and top of the adhesion layer 65, a metallic or plating layer 75 and a conducting solder barrier layer 80 on the plating layer 75. The polymer layer 63 is positioned on the plating layer 75 and provided with a suitable opening 90 through which a portion of the solder bump 35 projects and makes metallurgical contact with the solder barrier layer 80. The polymer layer 63 for a given bump 35 may be patterned as an island as shown. The adhesion layer 65 may be composed of titanium, titanium-tungsten, or other materials that may both metallurgically bond with the conductor pad 50 and readily adhere to the passivation structure 55. The intermetallic layer 70 is an otherwise unwanted by-product of intermetallic interactions between the metallic layer 75 and the adhesion layer 65 during a high temperature process to cure the polymer layer 63 as described in more detail below. It is important to note however that the exemplary fabrication processes disclosed herein are tailored to prevent the intermetallic layer 70 from forming across the upper surface 95 of the passivation structure 55. This is to prevent the intermetallic layer 70 from otherwise shorting directly to other solder bumps such as the adjacent solder bumps 40 and 45 shown in FIG. 1. Additional details regarding these fabrication techniques to restrain the lateral progression of the intermetallic layer 70 will be described in more detail below. The plating layer 75 is designed to facilitate the plating of the solder barrier layer 80 and the solder bump 35. A variety of materials may be used for this such as copper, gold or the like. Note that where titanium is selected for the adhesion layer 65 and copper is selected for the plating layer 75, the intermetallic layer will typically consist of a non-stoichiometric mixture or solution of titanium and copper with the formula TiₓCu_{y}, where x and y may not be integers. The solder barrier layer 80 may be composed of nickel, nickel vanadium, or other materials that may be both plated to the plating layer 75 and which provide a barrier to solder diffusion but metallurgical bond with the solder bump 35.

The solder bump 35 and the other solder bumps 25 shown in FIG. 1 may be composed of a variety of lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. Referring again briefly to FIG. 1, the solder structures 30 of the circuit board 20 may be composed of the same types of materials. Optionally, the solder structures 30 may be eliminated in favor of a single solder structure or a solder plus a conducting post arrangement.

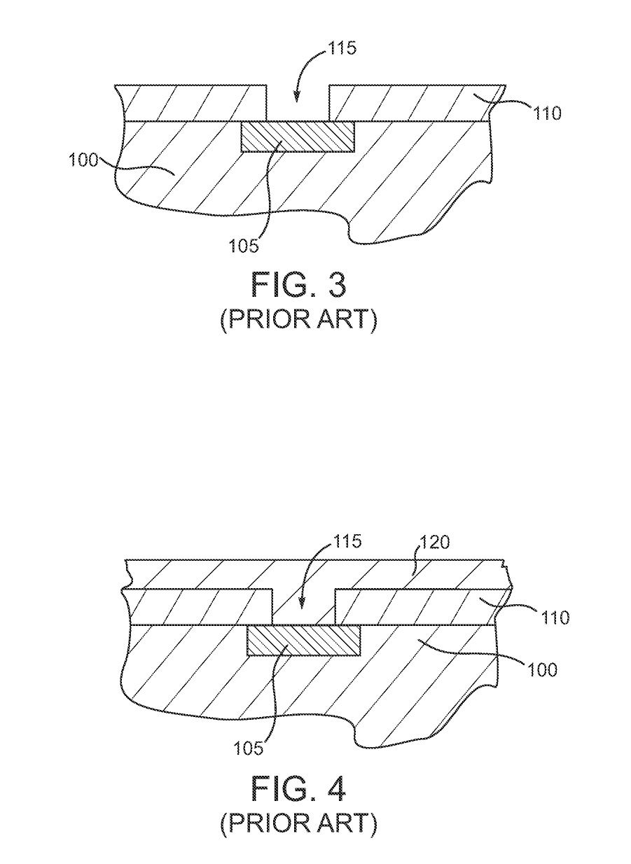

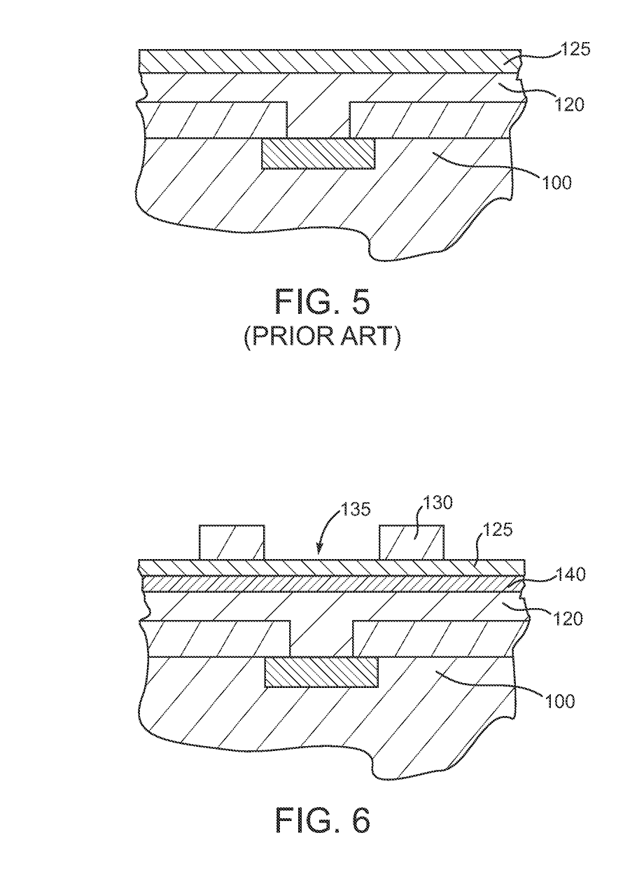

Before turning to an exemplary fabrication process to establish the plural solder bumps 25, including the exemplary solder bump 35, it may be instructive to first describe an existing process for fabricating a solder bump. This process will be described in conjunction with FIGS. 3, 4, 5, 6, 7, 8, 9 and 10. Attention is initially turned to FIG. 3, which is a sectional view like FIG. 2 but of an exemplary conventional semiconductor chip 100 that includes a conductor pad 105 and a passivation structure 110. At this stage, the passivation structure 110 has been patterned lithographically to establish an opening 115 that exposes a portion of the underlying conductor pad 105. Next and as shown in FIG. 4, the semiconductor chip 110 is subjected to sputter deposition of titanium to form an adhesion layer 120 on the passivation structure 110 that fills the opening 115 and establishes ohmic contact with the underlying conductor pad 105. Next and as shown in FIG. 5, the semiconductor chip 100 is subjected to sputter deposition of copper to form a plating layer 125 on the titanium adhesion layer 120. Next and as shown in FIG. 6, the semiconductor chip 100 is subjected to a polyimide coating process and the polyimide layer is lithographically patterned to establish the patterned polyimide layer 130 on the plating layer 125. The polyimide layer 130 includes photoactive compounds that permit lithographic patterning of an opening 135 and an island footprint as shown. The lithographic patterning includes a post-exposure bake step. The bake process creates an intermetallic layer 140 due to interactions between the copper plating layer 125 and the titanium adhesion layer 120. This intermetallic layer 140 is again typically a non-stoichiometric solid solution of titanium and copper with a formula TiₓCu_{y}. Note that this intermetallic layer 140 will form wherever there is a titanium to copper interface for the semiconductor chip 100.

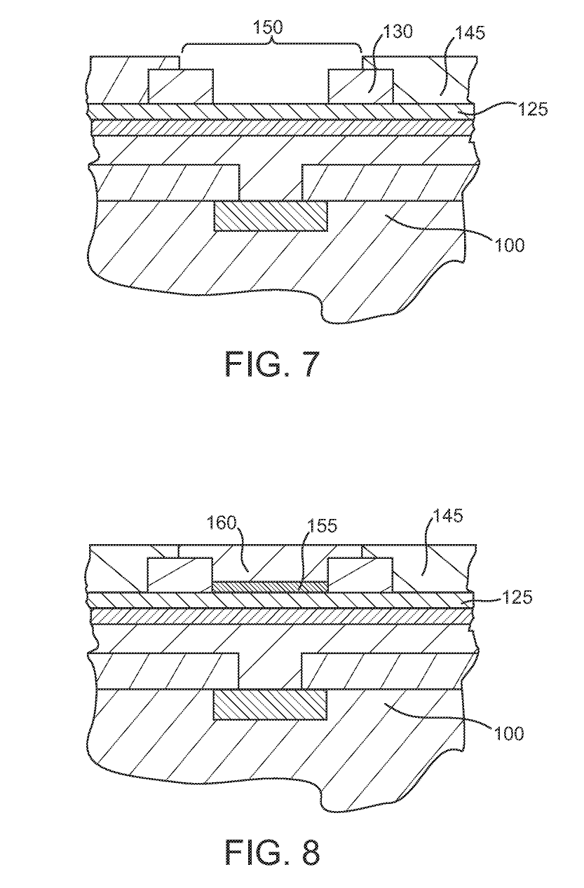

Referring now to FIG. 7, a dry film 145 is formed on both the polymer layer 130 and the plating layer 125 and patterned with a suitable opening 150. The opening 150 will serve as a site for subsequent solder barrier and solder constituent plating steps associated with the semiconductor chip 100. Next and as shown in FIG. 8, the semiconductor chip 100 is subjected to a two step plating process to establish a solder barrier layer 155 composed of nickel and positioned on the plating layer 125, and a plated solder portion 160 on the solder barrier layer 155. The dry film 145 will be removed following the plating of the solder 160.

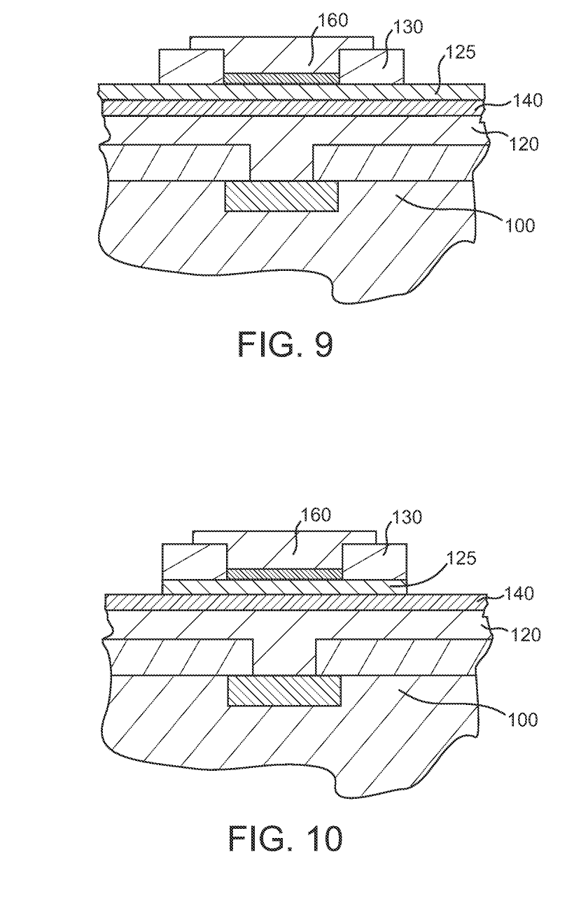

As shown in FIG. 9, the dry film 145 depicted in FIG. 8 is removed to leave the polymer layer 130 and a portion of the solder 160 exposed. At this stage, the blanket nature of the plating layer 125, the intermetallic layer 140 and the adhesion layer 120, if left alone, would essentially short every solder bump of the semiconductor chip 100 that those particular layers contact. Thus, it is desirable to perform some sort of material removal process to remove portions of the layers 120, 140 and 125 lateral to a given bump site. Thus, and as shown in FIG. 10, the semiconductor chip 100 is subjected to an etch step using the polymer layer 130 as an etch mask. The etch process is theoretically designed to etch portions of the layers 125, 140 and 120 lateral to the position of the solder structure 160. However, the unwanted intermetallic compound layer 140 is extraordinarily resistant to the types of etch processes used to etch the plating layer 125. Accordingly, the intermetallic layer 140 remains following the etch to pattern the plating layer 125 and continues to provide an unwanted electrical shorting between adjacent solder bumps.

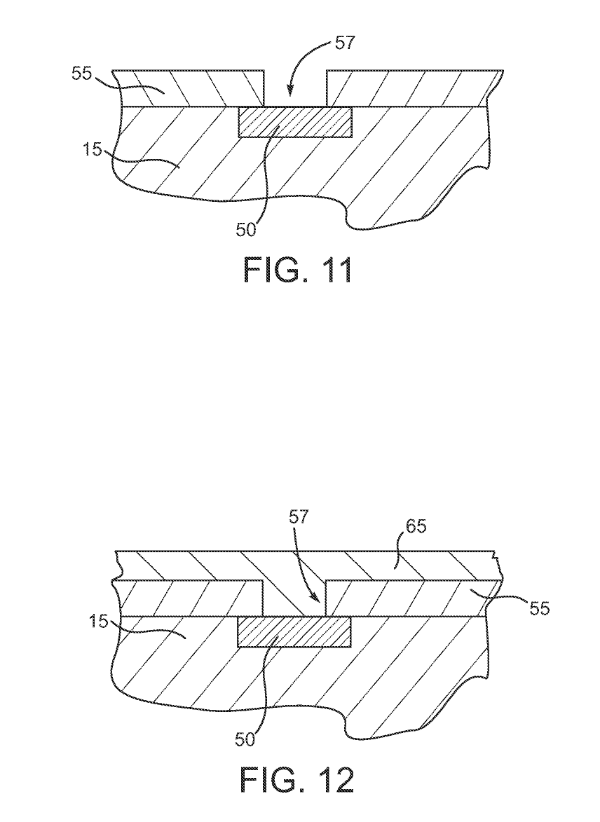

An exemplary process flow for fabricating the UBM 60 and the solder bump 35 depicted in FIG. 2 and which overcomes the troublesome difficulty in etching the intermetallic compound layer 70 will be described now in conjunction with FIGS. 11, 12, 13, 14, 15, 16, 17, 18 and 19. The process will focus on UBM 60 and the solder bump 35, but will be illustrative of the other solder bumps 25 and related structures shown in FIG. 1. Attention is initially turned to FIG. 11, which depicts the semiconductor chip 15 following the fabrication of a conductor pad 50 and the passivation structure 55. These steps and the steps that follow may be performed at the wafer level or on a die basis. The conductor pad 50 is electrically connected to another conductor structure in the chip 15 that may be part of the plural metallization layers in the semiconductor chip 15. The conductor pad 50 may be used as an input/output site for power, ground or signals or may be used as a dummy pad that is not electrically tied to other structures. The conductor structure 50 may form part of what may be multiple layers of conductor structures and interconnected by vias and surrounded by dielectric material layers (not shown). The conductor pad 50 may be composed of a variety of conductor materials, such as aluminum, copper, silver, gold, titanium, refractory metals, refractory metal compounds, alloys of these or the like. In lieu of a unitary structure, the conductor pad 50 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductor pad 50. Various well-known techniques for applying metallic materials may be used, such as physical vapor deposition, chemical vapor deposition, plating or the like. It should be understood that additional conductor structures could be used.

The passivation structure 55 may consist of alternating layers of dielectric materials, such as silicon dioxide and silicon nitride, and may be formed by well-known chemical vapor deposition (CVD) and/or oxidation or oxidation techniques. A suitable lithography mask (not shown) may be formed on the passivation structure 55 and by well-known lithography steps patterned with a suitable opening in alignment with the conductor pad 50. Thereafter, one or more material removal steps may be performed in order to produce the opening 57 in the passivation structure 55 so that the conductor pad 50 is exposed. For example, the material removal steps may include one or more dry and/or wet etching processes suitable for the particular materials selected for the passivation structure 55. Following the material removal to yield the opening 57, the mask (not shown) may be stripped by ashing, solvent stripping or the like.

The fabrication of the UBM 60 will now be described in conjunction with FIGS. 12-18. The skilled artisan will appreciate that a UBM is designed to bond to an overlying solder bump or other solder structure, to establish a conductive interface with an underlying conductor structure, in this case the conductor pad 50, to bond as necessary with underlying or surrounding dielectrics, all while providing a barrier to the diffusion of solder constituents into underlying conductor structures, which might otherwise degrade those conductor structures. UBMs may use multiple layers of different compositions depending on the type of solder application process. In this illustrative embodiment suitable for a plated solder bump, the UBM 60 may be formed as a series of layers applied in succession. The UBM 60 may consist of an adhesion layer of the type described above, followed by a plating layer, such as copper or gold deposited by electroless plating or sputter deposition, followed by a nickel or nickel-vanadium barrier layer of the type described above.

Next and as shown in FIG. 12, the semiconductor chip 15 may be subjected to a blanket sputter deposition process to apply the adhesion layer 65. In an exemplary embodiment, this sputter process involved sputter deposition of titanium, though aluminum or titanium-tungsten could also be used. The adhesion layer 65 blanket coats the passivation structure 55 and fills the opening 57 to establish ohmic contact with the conductor pad 50.

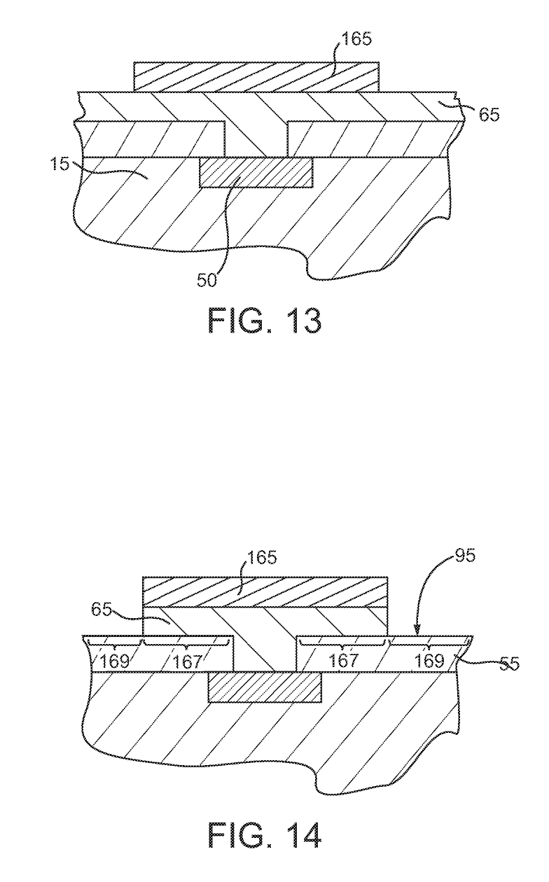

As shown in FIG. 13, a mask 165 is formed on the adhesion layer 65 and particularly at the location slated for eventual solder bump attachment and thus in alignment with the conductor pad 50. The mask 165 may be formed from positive tone resist, a hard mask or a non-contact mask. Patterning may be by well-known photolithography. Contrast this to the conventional process described above in conjunction with FIGS. 3-10 and in particular as shown in FIG. 5 where blanket copper sputtering of the plating layer 125 is done immediately after the sputtering of the adhesion layer 120. Here, the mask 165 will serve as an etch mask to reduce the lateral extent of the adhesion layer 65 to just that portion necessary for the eventual bump attachment to the semiconductor chip 15.

Thus, and as shown in FIG. 14, an etch process is performed to reduce the size of the adhesion layer 65. Following the etch, the adhesion layer 65 covers a portion 167 but does not cover other portion(s) 169 of the upper surface 95 of the passivation structure 55. In essence, the adhesion layer 65 is patterned like an island. The etch chemistry and process suitable for etching the adhesion layer 65 will depend upon the composition of the layer 65. In an exemplary embodiment where the adhesion layer 65 is composed of titanium, a wet HF etch may be used. Although technically more complex, an island-like adhesion layer could be alternatively constructed by selective material addition, such as by lift-off processing.

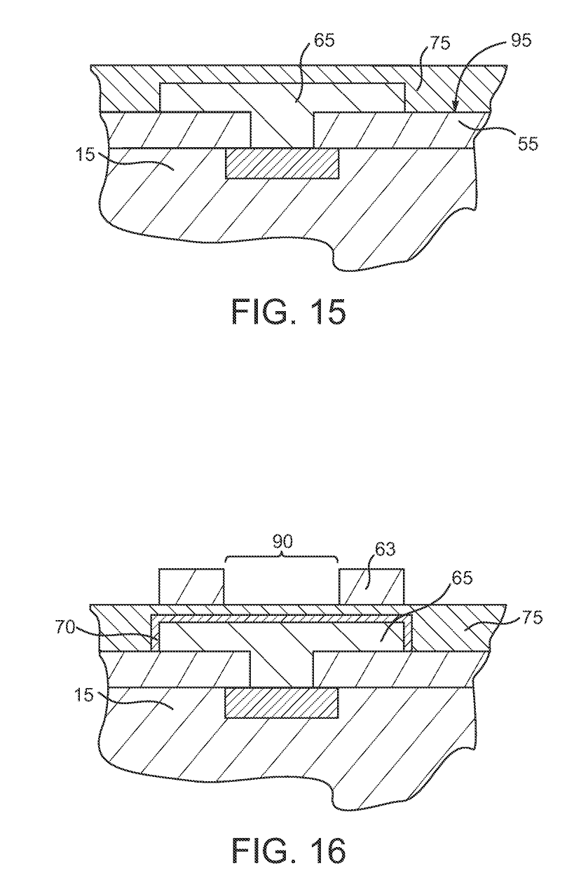

The mask 165 depicted in FIG. 14 may be removed by ashing, solvent stripping or the like from the adhesion layer 165 as shown in FIG. 15. Next, the semiconductor chip 15 may be subjected to a blanket sputtering, electroless plating or other deposition technique to apply the plating layer 75 on the adhesion layer 65 and the otherwise exposed portions of the upper surface 95 of the passivation structure 55. Note that in this illustrative process, the etch definition of the adhesion layer 65 reduces the intermetallic interface between the layers 65 and 75 down to essentially the outline of the adhesion layer 65. Thus, even if an intermetallic compound forms between the layers 65 and 75, such as the intermetallic layer 70 depicted in FIG. 2, the otherwise troublesome layer 70 will be confined to the location of the adhesion layer 65 as shown in FIG. 2 and thus not create an unetchable layer that leads to short circuits.

Next and as shown in FIG. 16, the polymer layer 63 is formed on the plating layer 75 and patterned with the opening 90 and an island footprint in advance of a subsequent solder barrier layer and solder material plating processes. The polymer layer 63 is designed to provide a compliant protective layer and thus may be composed of a variety of materials, such as polyimide, benzocyclobutene or other insulating materials such as silicon nitride or the like and may be deposited by spin coating, CVD or other techniques. If desired, the polymer layer 63 may be composed of polyimide infused with photoactive compounds to enable the photolithographic patterning of the opening 90. The semiconductor chip 15 is subjected to a bake process to cure the polymer layer 63. As noted above, this bake process results in the formation of the intermetallic compound 70 composed of TiₓCu_{y} if titanium and copper are used for example. However, since the adhesion layer 65 is cut down in size prior to the deposition of the plating layer 75, the intermetallic compound layer 70 is confined only to the much smaller interface between the adhesion layer 65 and the plating layer 75. If the polymer layer 63 is not capable of material removal by way of exposure and developing, then a suitable lithography mask may be applied and an etch performed to yield the requisite openings.

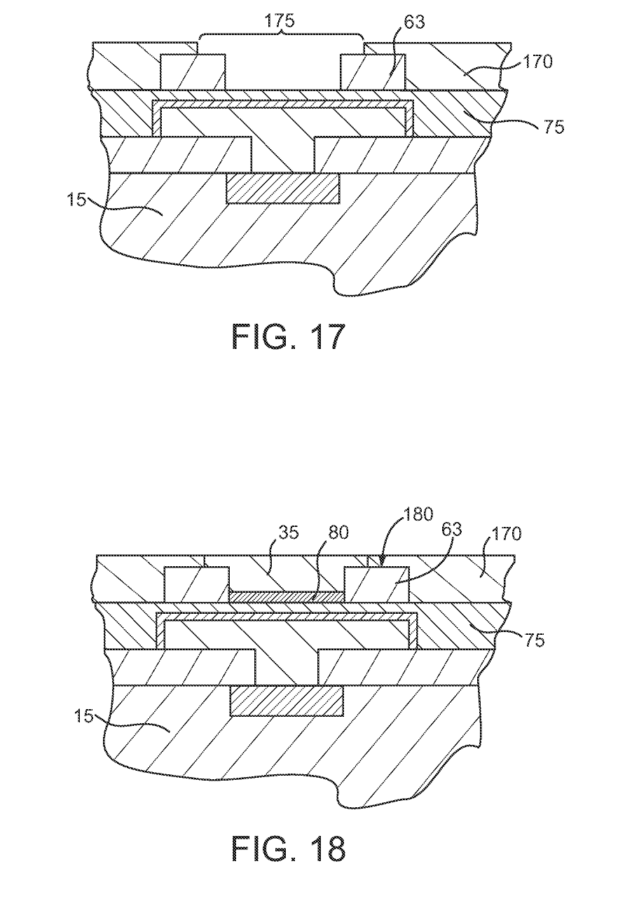

Next and as depicted in FIG. 17, a dry film 170 may be formed on the semiconductor chip 15 and in particular on the polymer layer 63 and the otherwise exposed portions of the plating layer 75 and patterned with a suitable opening 175 that will facilitate the subsequent plating of a solder barrier layer and a solder structure. The dry film 170 may be composed of negative tone resist or hard mask materials that may be lithographically patterned and etched to establish the opening 175.

Next and as depicted in FIG. 18, plating processes may be performed with the dry film 170 in place to apply first the solder barrier layer 80 and then the overlying solder structure 35. The solder structure 35 will through a subsequent reflow process change shape to the solder bump 35 depicted in FIG. 2. Note that the opening 175 is sized so that a portion of the solder structure 35 plates onto an upper surface 180 of the polymer layer 63 as shown.

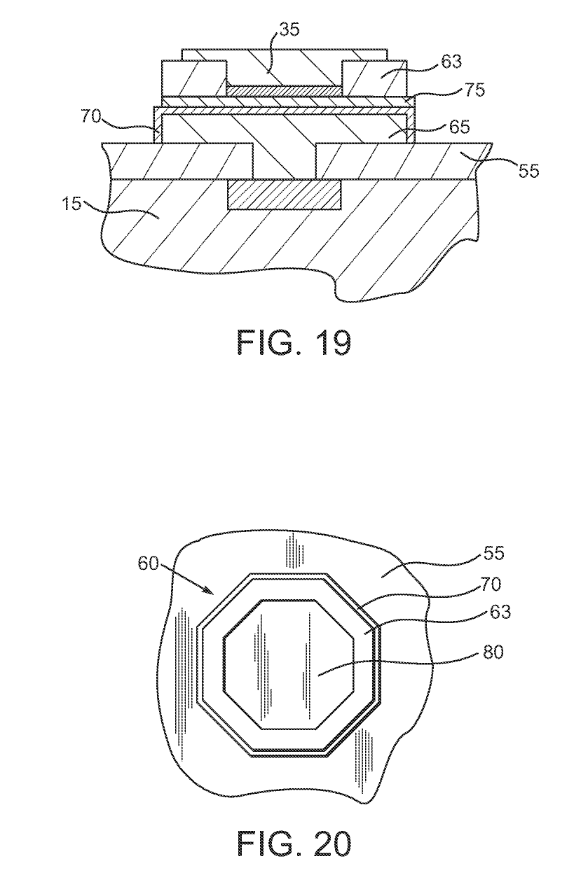

The dry film 170 is removed by ashing, solvent stripping or the like to leave the solder structure 35 and the polymer layer 63 exposed as shown in FIG. 19. At this stage, it is necessary to perform a material removal process in order to remove portions of the plating layer 75 that are lateral to the location of the solder structure 35. Otherwise, the plating layer as shown in FIG. 18 will short to adjacent bump locations such as the bumps 45 and 40 depicted in FIG. 1. The plating layer 75 may be etched using the polymer layer 63 as an etch mask using, for example, a hot phosphoric acid dip or other material removal process suitable for removing material from the plating layer 75. A hot phosphoric acid dip will typically be isotropic. While such an etch process will not significantly attack the intermetallic layer 170, that deficiency is of no consequence since the intermetallic layer 170 is confined to the location of the patterned adhesion layer 65. The semiconductor chip 15 and in particular the solder structure 35 may undergo a reflow process to establish the more rounded solder bump 35 depicted in FIG. 2. Of course the semiconductor chip 15 may be thereafter coupled to the circuit board 20 and subsequent reflow process performed to establish solder joints between the solder bumps 25 and the solder structures 30 depicted in FIG. 1.

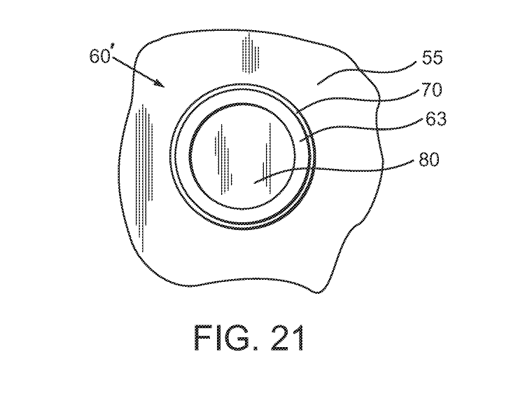

FIGS. 20 and 21 depict successive plan views of embodiments of the UBM. FIG. 20 depicts the UBM 60 with a generally octagonal footprint. Note that the polymer layer 63 is visible but only portions of the passivation structure 55, the barrier layer 80 and the intermetallic compound layer 70 are visible. FIG. 21 depicts a plan view of an alternate UBM 60′ that has a generally circular footprint. Again, the polymer layer 63 is visible but only portions of the passivation structure 55, the barrier layer 80 and the intermetallic compound layer 70 are visible. Of course, the UBMs 60 and 60′ may take on a variety of different types of footprints.

The solder interconnect structures disclosed herein are not dependent on particular functionalities of either the semiconductor chip 15 or the circuit board 20. Thus, the semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 15 may be constructed of bulk semiconductor, such as silicon or germanium, or semiconductor on insulator materials, such as silicon-on-insulator materials. The semiconductor chip 15 may be flip-chip mounted to the circuit board 20 and electrically connected thereto by solder joints or other structures (not visible in FIG. 1 but shown in subsequent figures).

The circuit board 20 may be a semiconductor chip package substrate, a circuit card, or virtually any other type of printed circuit board. Although a monolithic structure could be used for the circuit board 20, a more typical configuration will utilize a build-up design. In this regard, the circuit board 20 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards. The circuit board 20 is provided with a number of conductor traces and vias and other structures in order to provide power, ground and signals transfers between the semiconductor chip 15 and another circuit device that is not shown. To facilitate those transfers, the circuit board 20 may be provided with input/outputs in the form of a pin grid array, a ball grid array, a land grid array or other type of interconnect scheme.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
providing a semiconductor chip having a conductor pad and a passivation structure over the conductor pad;
applying a first metallic layer on the passivation structure and in electrical contact with the conductor pad, the first metallic layer covering a first portion but not a second portion of the passivation structure;
applying a second metallic layer to the first metallic layer and the second portion of the passivation structure;
applying a polymer layer to the second metallic layer, the polymer layer including a first opening in alignment with the first metallic layer and exposing a portion of the second metallic layer; and
applying a conducting solder barrier layer to the exposed portion of the second metallic layer.

2. The method of claim 1, comprising applying a solder structure to the conducting solder barrier layer.

3. The method of claim 2, comprising reflowing the solder structure to form a solder bump.

4. The method of claim 2, wherein the applying the solder structure comprises plating solder.

5. The method of claim 4, wherein the applying the solder structure comprises applying a dry film to the second metallic layer with a second opening aligned with the first metallic layer and plating solder in the second opening.

6. The method of claim 1, wherein the second metallic layer comprises copper.

7. The method of claim 1, wherein the first metallic layer comprises titanium.

8. The method of claim 7, wherein applying the titanium layer comprises sputtering titanium and etching the titanium to cover the first portion but not the second portion of the passivation structure.

9. The method of claim 1, wherein the first metallic layer, the second metallic layer, the polymer layer and the conducting solder barrier layer are forming using in instructions disposed in a computer readable medium.

10. The method of claim 1, comprising coupling the semiconductor chip to a circuit board.

11. A method of coupling a semiconductor chip to a circuit board, the semiconductor chip having a first conductor pad, a passivation structure, and an underbump metallization in electrical contact with the conductor pad, the underbump metallization including a first metallic layer on the passivation structure and in electrical contact with the conductor pad, the first metallic layer covering a first portion but not a second portion of the passivation, a second metallic layer on the first metallic layer, a polymer layer on the second metallic layer, the polymer layer including a first opening in alignment with the first metallic layer and exposing a portion of the second metallic layer, and a conducting solder barrier layer on the exposed portion of the second metallic layer, comprising:
coupling a solder structure to the underbump metallization; and
coupling the solder structure to the circuit board.

12. The method of claim 10, wherein the circuit board comprises a semiconductor chip package substrate.

13. The method of claim 10, wherein the coupling the solder structure comprises plating solder.

14. The method of claim 12, wherein the coupling the solder structure comprises applying a dry film to the second metallic layer with a second opening aligned with the first metallic layer and plating solder in the second opening.

15. The method of claim 10, wherein the second metallic layer comprises copper.

16. The method of claim 10, wherein the first metallic layer is applied by sputtering titanium and etching the titanium to cover the first portion but not the second portion of the passivation structure.

17. An apparatus, comprising:
a semiconductor chip having a conductor pad and a passivation structure over the conductor pad;
a first metallic layer on the passivation structure and in electrical contact with the conductor pad, the first metallic layer covering a first portion but not a second portion of the passivation structure;
a second metallic layer on the first metallic layer;
a polymer layer on the second metallic layer, the polymer layer including a first opening in alignment with the first metallic layer and exposing a portion of the second metallic layer; and
a conducting solder barrier layer to the exposed portion of the second metallic layer.

18. The apparatus of claim 16, comprising a circuit board coupled to the semiconductor chip.

19. The apparatus of claim 16, comprising a solder structure on the conducting solder barrier layer.

20. The apparatus of claim 16, wherein the second metallic layer comprises copper.

21. The apparatus of claim 16, wherein the conducting solder barrier layer comprises nickel.
